(19) United States
(12) Patent Application Publication
(10) Pub. No.: US 2006/0211204 A1
(43) Pub. Date: Sep. 21, 2006

(54) NON-VOLATILE MEMORY AND METHOD OF FABRICATING THE SAME

(76) Inventors: Min-San Huang, Hsinchu (TW); Dah-Chuan Chen, Hsinchu County (TW); Liang-Chuan Lai, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,858

(22) Filed: Nov. 1, 2005

(30) Foreign Application Priority Data
Mar. 18, 2005 (TW) 94108315

(51) Int. Cl. H01L 21/336

(52) U.S. Cl. 438/259

(57) ABSTRACT

A method for fabricating a non-volatile memory is disclosed. First, a semiconductor device is formed in a substrate, and the top of the semiconductor device is higher than the surface of the substrate. Then, a first dielectric layer is formed on the substrate, and the first dielectric layer covers the semiconductor device and the substrate. A portion of the first dielectric layer is removed so as to retain a portion of the first dielectric layer on the sidewall of the semiconductor device and the substrate. Afterwards, a second dielectric layer and a conductive layer are sequentially formed on the substrate, and a corresponding pair of mask spacers is formed on the conductive layer disposed on the sidewall of the semiconductor device. Finally, the mask spacers are used as an etching mask to continuously etch a portion of the conductive layer until the surface of the second dielectric layer is exposed.

### CROSS-REFERENCE TO RELATED APPLICATION

This application claims the priority benefit of Taiwan application serial no. 94108315, filed on Mar. 18, 2005. All disclosure of the Taiwan application is incorporated herein by reference.

### BACKGROUND OF THE INVENTION

1. Field of the Invention

The present invention relates to a semiconductor device and a method for fabricating the same, and more particularly, to a non-volatile memory and a method for fabricating the same.

2. Description of the Related Art

Memory, like its name, is a semiconductor device for storing information and data. Since it is an advantage of the non-volatile memory that the stored data is not lost even when the power is shut down, the non-volatile memory has become an indispensable component in various electronic products that the normal operation of the electronic products can be ensured. In addition, the non-volatile memory has become a widely accepted memory device in the personal computers (PC) and other electronic equipments.

Along with the continuous development of new technology, when the function of the computer microprocessor becomes more powerful and the size of the program codes/operations performed by the computer software is bigger, the requirement for the memory also becomes higher and higher. Especially, improvement of the write-in efficiency of the memory device has become essentially important. In order to meet the trend, the technique of fabricating the memory device has become a driving force for a challenge of the continuously higher integration level in the semiconductor technology.

FIGS. 1A through 1D schematically show sectional views of fabricating a non-volatile memory in the prior art.

Referring to FIG. 1A, a semiconductor device 101 is formed in a substrate 100, and the top of the semiconductor device 101 is higher than the surface of the substrate 100. Then, referring to FIG. 1B, a dielectric material layer 102 is formed on the substrate 100, and a conductive layer 104 is formed on the dielectric material layer 102. Referring to FIG. 1C, a pair of mask spacers 106 is formed on the conductive layer 104 disposed on the sidewall of the semiconductor device 101. Next, referring to FIG. 1D, the mask spacers 106 are used as an etching mask to continuously etch a portion of the conductive layer 104 and a portion of the dielectric material layer 102 until the surface of the substrate 100 is exposed. After the step of FIG. 1D, a conductive layer 104a retained on the dielectric material layer 102 is used as a word line.

However, the method for fabricating the non-volatile memory mentioned above has some drawbacks. For example, the write-in efficiency of the memory device is poor. In addition, in the step of etching the dielectric material layer 102, an encroach problem may be occurred in the dielectric layer of the semiconductor device 101 due to over etching, which deteriorates the reliability of the device. Similarly, in the step of etching the dielectric material layer 102, a breakdown problem may be occurred in the semiconductor device 101 and the word line due to over etching, which also seriously affects the performance of the device.

### SUMMARY OF THE INVENTION

Therefore, it is an object of the present invention to provide a method for fabricating a non-volatile memory. The method prevents the encroach problem from happening in the dielectric layer of the non-volatile memory. Accordingly, the quality of the film layer in the dielectric layer is improved, and the breakdown problem in device is eliminated, such that the reliability of the fabricating process is further improved.

It is another object of the present invention to provide a non-volatile memory, which provides an improved performance and write-in efficiency for the device.

The present invention provides a method for fabricating a non-volatile memory. First, a semiconductor device is formed in a substrate, and the top of the semiconductor device is higher than the surface of the substrate. Then, a first dielectric layer is formed on the substrate, and the first dielectric layer covers the surface of the semiconductor device and the substrate. Wherein, the surface profile of a portion of the first dielectric layer covering the substrate is presented in a ladder-like form gradually increasing to the full height of the semiconductor device. Then, a first conductive layer is formed on the first dielectric layer, and a first pair of mask spacers is formed on the first conductive layer disposed on the sidewall of the semiconductor device. Afterwards, the first pair of mask spacers is used as an etching mask to continuously remove a portion of the first conductive layer until the surface of the first dielectric layer is exposed. In addition, the first conductive layer between the first pair of mask spacers and the first dielectric layer forms a pair of conductive spacers.

In accordance with the preferred embodiment of the present invention, the method for forming the first dielectric layer mentioned above for example includes the following steps. First, a first dielectric material layer is formed on the substrate, and the first dielectric material layer covers the surface of the semiconductor device and the substrate. Then, the first dielectric material layer is removed so as to at least retain a portion of the first dielectric material layer on the surface of the semiconductor device and on a portion of the substrate. Then, a second dielectric material layer is formed on the substrate, and the second dielectric material layer covers the first dielectric material layer and the substrate.

In accordance with the preferred embodiment of the present invention, the method for removing a portion of the first dielectric material layer so as to at least retain part of the first dielectric material layer on the surface of the semiconductor device and on a portion of the substrate for example includes the following steps. First, a corresponding second pair of mask spacers is formed on the first dielectric material layer disposed on the sidewall of the semiconductor device. Then, the second pair of mask spacers is used as an etching mask to remove a portion of exposed first dielectric material layer. Then, the mask spacers are removed so as to continuously remove a portion of the first dielectric material layer on the semiconductor device sidewall and on the substrate until the surface of the substrate is exposed.

In accordance with the preferred embodiment of the present invention, the method for removing a portion of the first dielectric material layer on the semiconductor device sidewall and on the substrate until the surface of the substrate is exposed for example includes a wet etching method.

In accordance with the preferred embodiment of the present invention, the thickness of the first dielectric layer retained on a portion of the substrate disposed on the semiconductor device sidewall is 10˜20 Å.

In accordance with the preferred embodiment of the present invention, the dielectric material layer mentioned above is made of a material such as silicon oxide, and it is for example formed by a chemical vapor deposition method.

In accordance with the preferred embodiment of the present invention, the length ratio of the 1^{st} stage and 2^{nd} stage surfaces gradually increasing from the first dielectric layer toward the semiconductor device is 1:2.

In accordance with the preferred embodiment of the present invention, the first mask spacers mentioned above are made of a material such as silicon nitride. Wherein, the method for forming the first mask spacers for example includes the following steps. First, a mask material layer is formed on the first conductive layer. Then, an etching process is performed so as to remove a portion of the mask material layer.

In accordance with the preferred embodiment of the present invention, the semiconductor device mentioned above is for example a trench semiconductor device. The method for forming the trench semiconductor device for example includes the following steps. First, a trench is formed on the substrate. Then, a second dielectric layer, a second conductive layer, and a third dielectric layer are sequentially formed on the trench sidewall. Wherein, an opening is reserved in the trench, and the bottom of the opening exposes a portion of the substrate. Then, a source line is formed in the opening, wherein the source line is made of a material such as polysilicon.

In accordance with the preferred embodiment of the present invention, the method of using the first mask spacers as the etching mask to remove a portion of the first conductive layer further includes continuously removing the first conductive layer until the surface of the first dielectric layer is exposed.

The present invention further provides a non-volatile memory. The non-volatile memory includes a substrate, a semiconductor device, a first dielectric layer, and a first conductive layer. Wherein, a trench is disposed in the substrate, and the semiconductor device is disposed in the trench. The top of the semiconductor device is higher than the surface of the substrate. The first dielectric layer is disposed on the substrate, and the first dielectric layer covers the surface of the semiconductor device and the substrate. Wherein, the surface profile of a portion of the first dielectric layer covering the substrate is presented in a ladder-like form gradually increasing to the full height of the semiconductor device. In addition, a first conductive layer is formed on the first dielectric layer, and the first conductive layer covers a portion of the first dielectric layer on the sidewall of the semiconductor device.

In accordance with the preferred embodiment of the present invention, the length ratio of the 1^{st} stage and 2^{nd} stage surfaces gradually increasing from the first dielectric layer toward the semiconductor device is 1:2.

In accordance with the preferred embodiment of the present invention, the dielectric layer mentioned above is made of a material such as silicon oxide.

In accordance with the preferred embodiment of the present invention, the semiconductor device mentioned above is for example a trench semiconductor device. The trench semiconductor device includes a second dielectric layer, a second conductive layer, a source line, and a third dielectric layer. Wherein, the second dielectric layer is disposed on a trench sidewall and on a portion of the trench bottom in the substrate. The second conductive layer is disposed on the sidewall of the trench above the second dielectric layer. The source line is disposed in the trench, and the top of the source line is higher than the surface of the substrate. The third dielectric layer is disposed in the trench between the second conductive layer and the source line. The source line mentioned above is for example made of a material such as polysilicon.

The method for fabricating the non-volatile memory provided by the present invention forms a dielectric layer on the substrate, and the surface profile of the dielectric layer is presented in a ladder-like form. Thus, the film layer of the dielectric layer on a portion of the substrate closing to the sidewall of the semiconductor device is thicker. A higher resistance will be generated when a bias is provided, such that a higher electric field is generated in the channel below the dielectric layer with a thicker film layer. Therefore, the electrons are accelerated and the write-in efficiency of the device is effectively improved. In addition, since in the step of continuously removing a portion of the first dielectric layer until the surface of the substrate is exposed, the time spent in the wet etching fabricating process to expose the surface of the substrate is shorter, thus the encroach phenomenon occurred in the dielectric layer of the semiconductor device resulted from the erosion of the trench from the etching liquor is effectively eliminated. Accordingly, the quality of the film layer of the dielectric layer in the semiconductor device is improved, and the performance of the device and the reliability of the fabricating process are both improved. In addition, since the film layer of the dielectric layer between the semiconductor device and the first conductive layer is thicker, the breakdown problem is effectively eliminated and the performance of the device will not be affected.

### BRIEF DESCRIPTION OF THE DRAWINGS

The accompanying drawings are included to provide a further understanding of the invention, and are incorporated in and constitute a part of this specification. The drawings illustrate embodiments of the invention, and together with the description, serve to explain the principles of the invention.

FIGS. 1A through 1D schematically show sectional views of fabricating a non-volatile memory in the prior art.

FIGS. 2A through 2J schematically show sectional views of fabricating a non-volatile memory according to a preferred embodiment of the present invention.

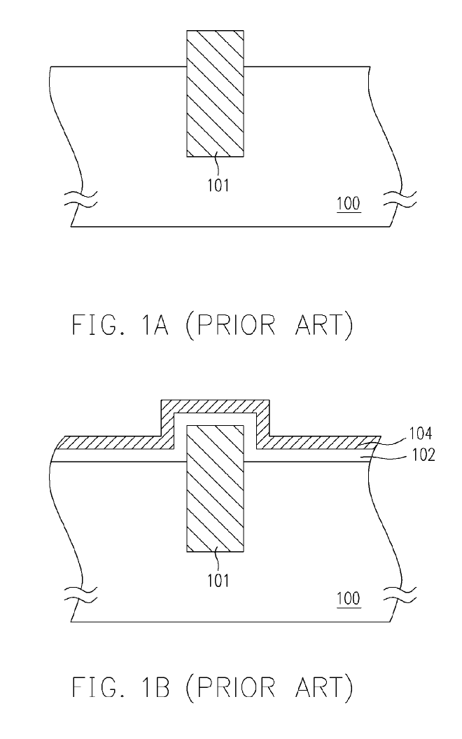

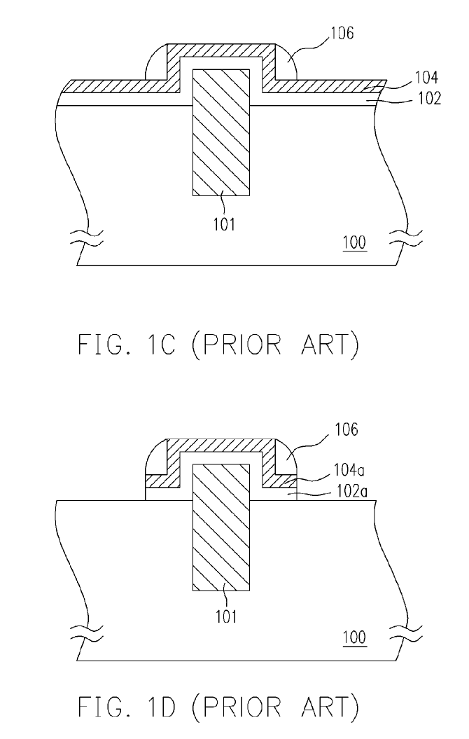

### DESCRIPTION OF THE PREFERRED EMBODIMENTS

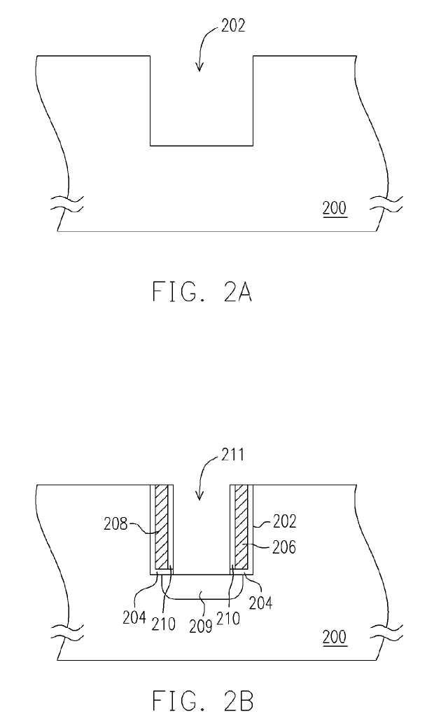

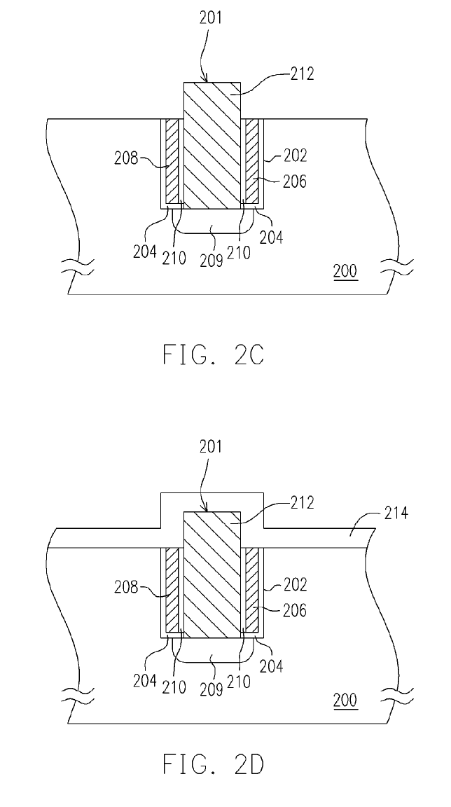

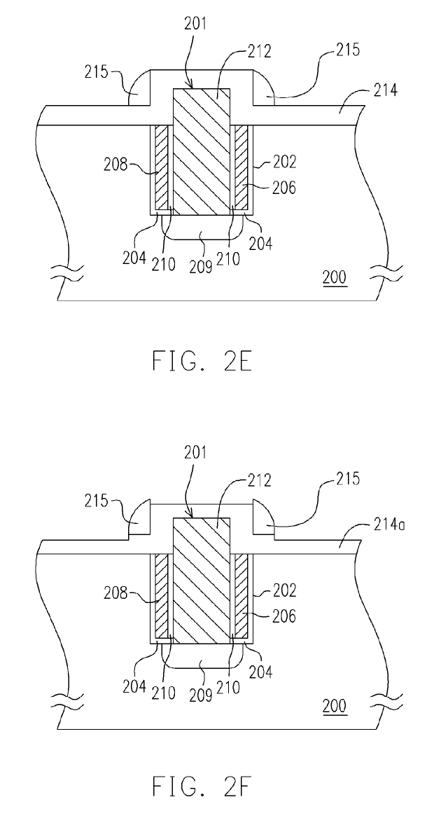

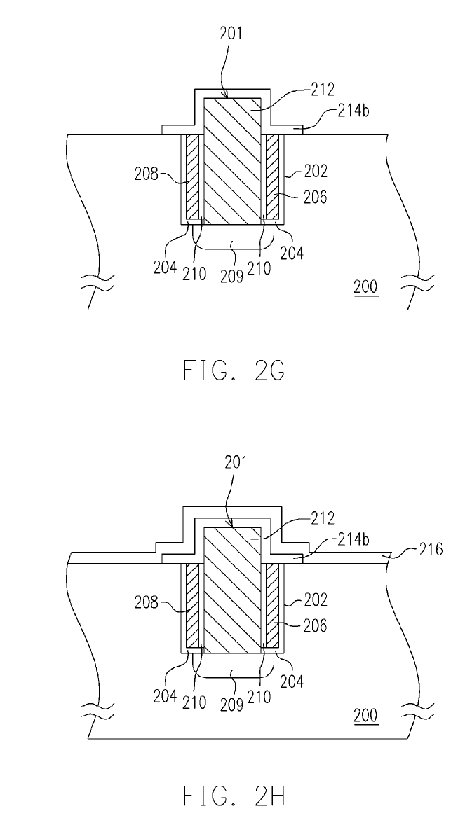

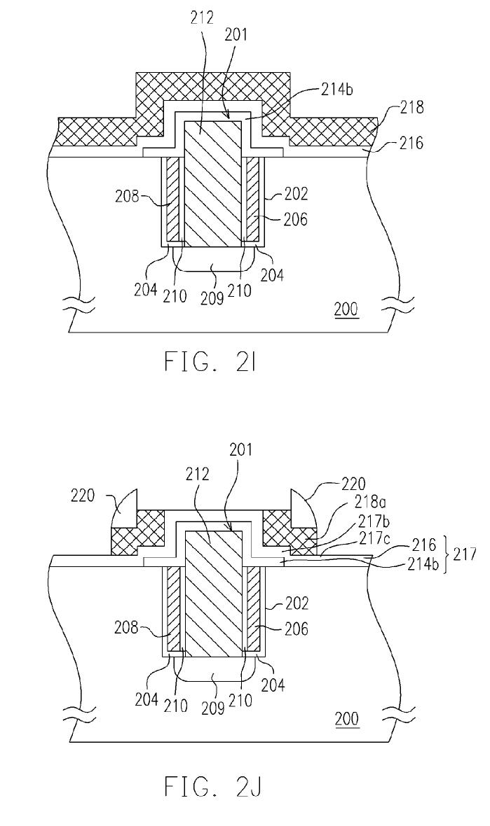

FIGS. 2A through 2J schematically show sectional views of fabricating a non-volatile memory according to a preferred embodiment of the present invention.

First, referring to FIG. 2A, a substrate 200 is provided. The substrate 200 is for example a silicon substrate, and a trench 202 is formed in the substrate 200. Wherein, the method for forming the trench 202 for example includes the following steps. First, a patterned mask material layer (not shown) is formed on the substrate 200, and the patterned mask material layer is for example made of a material such as silicon nitride and formed by the chemical vapor deposition method. Then, the patterned mask material layer is used as a mask to etch the substrate 200.

Then, referring to FIG. 2B, a tunnel oxide layer 204 is formed on the surface of the trench 202. The tunnel oxide layer 204 is for example made of a material such as silicon oxide and formed by a thermal oxidation method.

Afterwards, a conductive layer (not shown) is filled into the trench 202. Wherein, the conductive layer is made of a material such as doped polysilicon and formed by performing an ion implant process after a non-doped polysilicon layer is formed by the chemical vapor deposition method. Then, a portion of the conductive layer is continuously removed until the surface of the substrate 200 is exposed. Wherein, the method for removing a portion of the conductive layer mentioned above includes an etching back step, which is for example performed by a chemical mechanical polishing process. Then, a photolithographic process and an etching process are performed on the conductive layer so as to form two floating gates 206 and 208 on both sides of the trench 202. In an embodiment of the present invention, after these two floating gates 206 and 208 are formed, a doped region 209 is formed in the substrate 200 on the bottom of the trench 202 by an ion implant process.

Then, an inter-gate dielectric layer 210 is formed on the substrate 200, such as an internal poly oxidation (IPO). Then, a portion of the inter-gate dielectric layer 210 is removed so as to retain an opening 211 in the trench 202, and the bottom of the opening 211 exposes a portion of the substrate 200.

Afterwards, referring to FIG. 2C, a source line 212, which is for example made of polysilicon, is formed on the substrate 200. The top of the source line 212 is higher than the surface of the substrate 200 and the source line 212 fills up the opening 211 mentioned above. In an embodiment of the present invention, after the source line 212 is formed, another oxide layer is formed on the surface of the source line 212 for protecting the source line 212 in subsequent process. However, it is not illustrated in the present embodiment.

In FIG. 2C, after the source line 212 is formed in the opening 211, a trench semiconductor device 201 is formed in the substrate 200. The trench semiconductor device 201 mentioned above includes a tunnel oxide layer 204, two floating gates 206 and 208, a source line 212, and an inter-gate dielectric layer 210. It is apparent that the trench semiconductor device of the present invention may be configured as the other structure as long as the top of the structure is higher than the semiconductor device on the substrate, and it is not necessarily to be limited as the trench semiconductor device of the present embodiment mentioned above.

Then, referring to FIG. 2D, an inter-gate dielectric layer 214 is formed on the substrate 200, and it is for example a silicon oxide layer formed by the chemical vapor deposition method.

Then, referring to FIG. 2E, a corresponding pair of mask spacers 215 is formed on the inter-gate dielectric layer 214 disposed on the sidewall of the source line 212. The method for forming the mask spacers 215 for example includes the following steps. First, a mask material layer is formed on the inter-gate dielectric layer 214 with a material such as silicon nitride, and then an anisotropic etching process is performed on the mask material layer.

Then, referring to FIG. 2F, the mask spacers 215 are used as an etching mask to remove a portion of the inter-gate dielectric layer 214, such that an inter-gate dielectric layer 214a is formed. Afterwards, referring to FIG. 2G, the mask spacers 215 are removed, and a portion of the inter-gate dielectric layer 214a is continuously removed until the surface of the substrate 200 is exposed, such that an inter-gate dielectric layer 214b is formed. The thickness of the inter-gate dielectric layer 214b is for example 10˜20 Å. Wherein, the method for continuously removing a portion of the inter-gate dielectric layer 214a until the surface of the substrate 200 is exposed mentioned above for example is performed by an isotropic wet etching process.

To be noted that since the thickness of the film layer of the exposed inter-gate dielectric layer 214a is thinner than the thickness of the film layer of the inter-gate dielectric layer 214a covered by the mask spacers 215 (as shown in FIG. 2F), in the step of continuously removing a portion of the inter-gate dielectric layer 214a until the surface of the substrate 200 is exposed, the time spent in performing the wet etching process to expose the surface of the substrate 200 is shortened. In other words, since the time spent in the wet etching process mentioned above is shorter, the encroach phenomenon occurred in the tunnel oxide layer 204 caused by the erosion of the trench 202 from the etching liquor is effectively eliminated. Accordingly, the quality of the film layer of the tunnel oxide layer 204 is enhanced, and the performance of the device and the reliability of the fabricating process are both improved. On the other hand, since the time spent in the wet etching process mentioned above is shorter, the inter-gate dielectric layer 214 on the sidewall of the source line 212 is not completely removed and a partial thickness of the inter-gate dielectric layer 214 is still retained, which facilitates subsequent process.

In another embodiment of the present invention, the method for forming the inter-gate dielectric layer 214b mentioned above for example includes the following steps. First, the mask spacers 215 are used as an etching mask to directly remove the inter-gate dielectric layer 214 of FIG. 2E until the surface of the substrate 200 is exposed, and then the mask spacers 215 are removed.

Then, referring to FIG. 2H, another inter-gate dielectric layer 216 is formed on the substrate 200. The inter-gate dielectric layer 216 is for example a silicon oxide layer formed by the chemical vapor deposition method. Both the inter-gate dielectric layers 214b and 216 can work together as an isolation layer for isolating two neighbouring conductive layers. More specifically, the surface profile of the inter-gate dielectric layers 214b and 216 is presented in a ladder-like form gradually increasing to the full height of the trench semiconductor device 201. Therefore, the film layer of the dielectric layer on a portion of the substrate close to the sidewall of the semiconductor device is thicker. A higher resistance will be generated when a bias is provided, such that a higher electric field is generated in the channel below the dielectric layer with a thicker film layer. Therefore, the electrons are accelerated and the write-in efficiency of the device is effectively improved.

To be noted that the ladder-like form inter-gate dielectric layer mentioned above may be formed by a single etching process. The present invention should not be limited by it.

Then, referring to FIG. 2I, a conductive layer 218 is formed on the inter-gate dielectric layer 216, and the conductive layer is made of a material such as doped polysilicon.

Then, referring to FIG. 2J, a pair of mask spacers 220 is formed on the conductive layer 218 disposed on the sidewall of the source line 212. The method for forming the mask spacers 220 for example includes the following steps. First, a mask material layer is formed on the conductive layer 218 with a material such as silicon nitride, and then an anisotropic etching process is performed on the mask material layer. Then, the mask spacers 220 are used as an etching mask to continuously remove a portion of the conductive layer 218 until the surface of the inter-gate dielectric layer 216 is exposed, such that a pair of conductive spacers 218a is formed. The pair of conductive spacers 218a is used as a word line. Wherein, the ratio of the length of the inter-gate dielectric layer 214b below the conductive spacers 218a to the length of the inter-gate dielectric layer 216 below the conductive spacers 218a not covering the inter-gate dielectric layer 214b is preferable as 1:2.

As described above, the inter-gate dielectric layer 214b is retained on the sidewall of the source line 212 (as shown in FIG. 2G), the film layer of the inter-gate dielectric layer between the source line 212 and the conductive spacers 218a (that is, the film layer of the inter-gate dielectric layer 216 and the inter-gate dielectric layer 214b) is thicker. Accordingly, the source line 212 is effectively isolated from the word line (i.e. the conductive spacers 218a), such that the performance of the device and the reliability of the fabricating process are not affected.

The structure of the non-volatile memory obtained by the method for forming the non-volatile memory mentioned above is described in detail hereinafter.

Referring to FIG. 2J, the structure of the non-volatile memory includes a substrate 200, a trench semiconductor device 201, an inter-gate dielectric layer 214b, an inter-gate dielectric layer 216, and a conductive spacer 218a.

Wherein, the substrate 200 has a trench 202. The trench semiconductor device 201 is disposed in the trench 202, and the top of the trench semiconductor device 201 is higher than the surface of the substrate 200. The trench semiconductor device 201 mentioned above includes a tunnel oxide layer 204, floating gates 206 and 208, a source line 212, and an inter-gate dielectric layer 210. The tunnel oxide layer 204 is disposed on the sidewall of the trench 202 and the bottom of a portion of the trench 202. The floating gates 206 and 208 are disposed on the sidewall of the trench 202 above the tunnel oxide layer 204, respectively. The source line 212 is disposed in the trench 202, and the top of the source line 212 is higher than the surface of the substrate 200. The source line 212 is made of a material such as polysilicon. The inter-gate dielectric layer 210 is disposed in the trench 202 between the source line 212 and the floating gates 206 and 208.

In addition, the inter-gate dielectric layer 214b and 216 can be combined as an inter-gate dielectric layer 217 for using as an isolation layer between the trench semiconductor device 201 and the conductive spacer 218a. The inter-gate dielectric layer 217 is disposed on the substrate 200 and covers the surface of the trench semiconductor device 201 and the substrate 200. The surface profile of a portion of the inter-gate dielectric layer 217 covering the substrate 200 is presented in a ladder-like form gradually increasing to the full height of the trench semiconductor device 201. Specifically, the inter-gate dielectric layer 217 mentioned above is disposed in a shape of ladder, thus the dielectric layer on the sidewall of the trench semiconductor device 201 is thicker. Accordingly, a higher resistance is generated, which facilitates improving the performance of the device.

The inter-gate dielectric layer 217 mentioned above is made of a material such as silicon oxide, and the thickness of the inter-gate dielectric layer 214b is 10˜20 Å. The length ratio of the 1^{st} stage and 2^{nd} stage surfaces gradually increasing from the inter-gate dielectric layer 217 toward the trench semiconductor device 201 is preferable as 1:2.

The conductive spacer 218a is disposed on the inter-gate dielectric layer 217 and covers a portion of the inter-gate dielectric layer 217 on the sidewall of the trench semiconductor device 201.

It is apparent that the trench semiconductor device of the present invention is not limited to the structure described in the embodiment mentioned above. Other structures may be applied to the method of the present invention as long as the top of the structure is higher than the surface of the substrate in the semiconductor device.

In addition, it is to be noted that when the data write-in operation is performed on the non-volatile memory, after a bias is applied to the source line 212 of the semiconductor device 201, the electrons are injected into the floating gate 204 or 206 through a channel in the substrate 200 below the conductive spacer 218a. However, since the inter-gate dielectric layer 217 on the substrate 200 disposed on the side of the source line 212 is thicker than the film layer of the conventional signal inter-gate dielectric layer, a higher resistance is generated. Accordingly, a higher electric field is generated in the channel below the inter-gate dielectric layer 217 above the substrate 200, such that the electrons are accelerated and injected into the floating gate 204 or 206 with a higher speed, and the efficiency of data write-in is effectively improved.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A method for fabricating a non-volatile memory, comprising:
forming a semiconductor device in a substrate, and a top of the semiconductor device being higher than a surface of the substrate;
forming a first dielectric layer on the substrate for covering a surface of the semiconductor device and the substrate, wherein a surface profile of a portion of the first dielectric layer covering the substrate is represented in a ladder-like form gradually increasing to a full height of the semiconductor device;
forming a first conductive layer on the first dielectric layer;
forming a pair of first mask spacers on the first conductive layer disposed on the sidewalls of the semiconductor device; and
removing the first conductive layer by using the pair of the first mask spacers as an etching mask, and forming a pair of conductive spacers between the pair of the first mask spacers and the first dielectric layer.

2. The method for fabricating the non-volatile memory of claim 1, wherein the step for forming the first dielectric layer comprises:
forming a first dielectric material layer on the substrate and covering the surface of the substrate and the substrate;
removing a portion of the first dielectric material layer to at least retain a portion of the first dielectric material layer on the surface of the semiconductor device and on a portion of the substrate; and
forming a second dielectric material layer on the substrate, and covering the first dielectric material layer and the substrate.

3. The method for fabricating the non-volatile memory of claim 2, wherein the step for removing a portion of the first dielectric material layer to at least retain a portion of the first dielectric material layer on the surface of the semiconductor device and on a portion of the substrate comprises:
forming a pair of second mask spacers on the first dielectric material layer disposed on the sidewalls of the semiconductor device;
removing a portion of the exposed first dielectric material layer by using the pair of the second mask spacers as an etching mask;
removing the second mask spacers; and
removing a portion of the first dielectric material layer on the sidewall of the semiconductor device and on the substrate until exposing the surface of the substrate.

4. The method for fabricating the non-volatile memory of claim 3, wherein the step for removing a portion of the first dielectric material layer on the sidewall of the semiconductor device and on the substrate until exposing the surface of the substrate comprises using a wet etching method.

5. The method for fabricating the non-volatile memory of claim 2, wherein a thickness of the first dielectric material layer retained on the sidewall of the semiconductor device is 10˜20 Å.

6. The method for fabricating the non-volatile memory of claim 2, wherein the material of the first dielectric material layer comprises silicon oxide.

7. The method for fabricating the non-volatile memory of claim 2, wherein the first dielectric material layer is formed by using a chemical vapor deposition method.

8. The method for fabricating the non-volatile memory of claim 1, wherein a ratio of lengths for a 1^{st} stage and a 2^{nd} stage surfaces gradually increasing from the first dielectric layer toward the semiconductor device is 1:2.

9. The method for fabricating the non-volatile memory of claim 1, wherein the material of the pair of the first mask spacers comprises silicon nitride.

10. The method for fabricating the non-volatile memory of claim 1, wherein the step for forming the pair of the first mask spacers comprises:
forming a mask material layer on the first conductive layer; and
performing an etching process to remove a portion of the mask material layer.

11. The method for fabricating the non-volatile memory of claim 1, wherein the semiconductor device comprises a trench semiconductor device.

12. The method for fabricating the non-volatile memory of claim 11, wherein the step for forming the trench semiconductor device comprises:
forming a trench in the substrate;
forming a second dielectric layer, a second conductive layer, and a third dielectric layer on the sidewall of the trench, wherein the trench has an opening, and a bottom of the opening exposes a portion of the substrate; and
forming a source line in the opening.

13. The method for fabricating the non-volatile memory of claim 12, wherein the material of the source line comprises polysilicon.

14. The method for fabricating the non-volatile memory of claim 1, wherein the step for using the pair of the first mask spacers as an etching mask to remove a portion of the first conductive layer further comprises removing a portion of the first conductive layer until exposing the surface of the first dielectric layer.

15. A non-volatile memory, comprising:
a substrate having a trench formed therein;
a semiconductor device disposed in the trench, and a top of the semiconductor device being higher than a surface of the substrate;
a first dielectric layer disposed on the substrate for covering a surface of the semiconductor device and the substrate, wherein a surface profile of a portion of the first dielectric layer covering the substrate is in a ladder-form, gradually increasing to a full height of the semiconductor device; and
a first conductive layer, disposed on the first dielectric layer for covering a portion of the first dielectric layer on a sidewall of the semiconductor device.

16. The non-volatile memory of claim 15, wherein a ratio of lengths for a 1^{st} stage and a 2^{nd} stage surfaces gradually increasing from the first dielectric layer toward the semiconductor device is 1:2.

17. The non-volatile memory of claim 15, wherein the material of the first dielectric layer comprises silicon nitride.

18. The non-volatile memory of claim 15, wherein the semiconductor device comprises a trench semiconductor device.

19. The non-volatile memory of claim 18, wherein the trench semiconductor device comprises:
a second dielectric layer, disposed on a sidewall of a trench in the substrate and on a portion of a bottom of the trench;
a second conductive layer disposed on the sidewall of the trench above the second dielectric layer;
a source line disposed in the trench, and a top of the source line being higher than the surface of the substrate; and
a third dielectric layer disposed in the trench between the second conductive layer and the source line.

20. The non-volatile memory of claim 19, wherein the material of the source line comprises polysilicon.
